(19) United States
(12) Patent Application Publication
(10) Pub. No.: US 2006/0097292 A1
(43) Pub. Date: May 11, 2006

(54) Semiconductor device

(75) Inventors: Kazutoshi Nakamura, Yokohama-shi (JP); Tomoko Matsudai, Tokyo (JP); Norio Yasuhara, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/261,531

(22) Filed: Oct. 31, 2005

(30) Foreign Application Priority Data
Oct. 29, 2004 (JP) 2004-316699

(51) Int. Cl. H01L 29/76

(52) U.S. Cl. 257/288

(57) ABSTRACT

A semiconductor device includes a second conductivity type layer selectively formed by changing impurity concentrations on a semiconductor substrate, a first conductivity type source region formed on the second conductivity type layer, a first conductivity type drain region formed on the second conductivity type layer apart from the first conductivity type source region, a gate electrode formed between the first conductivity type source region and the first conductivity type drain region across an insulation film, and a second conductivity type contact layer formed adjacent to the first conductivity type source region, wherein the second conductivity type layer in the source region side has a higher impurity concentration than the impurity concentration of the second conductivity type layer in the drain region side.

### CROSS REFERENCE TO RELATED APPLICATIONS

This application is based upon and claims the benefit of priority under 35 USC §119 from the prior Japanese Patent Application No. 2004-316699 filed on Oct. 29, 2004, the entire contents of which are incorporated by reference.

### BACKGROUND

The present application relates to a semiconductor device, and more specifically, to a semiconductor device containing a metal oxide semiconductor field effect transistor (hereafter abbreviated as MOSFET) of low breakdown voltage used in a power IC (integrated circuit).

Heretofore, in DC-DC converters, such as a VRM (voltage regulator module) for mobile devices, a low breakdown voltage lateral MOSFET having a low on-resistance and higher reliability is required. FIG. 11 is a sectional view showing the sectional structure of a conventional low breakdown voltage MOSFET. In FIG. 11, a P-type semiconductor layer 2 is selectively formed on a P-type semiconductor substrate 1; An N⁺-type source region 3 and an N⁺-type drain region 4 are selectively formed on the P-type semiconductor layer 2. A gate electrode 6 is formed between the N⁺-type source region 3 and the N⁺-type drain region 4 across a gate oxide film 5, and a P⁺-type contact layer 7 is formed adjacent to the N⁺-type source region 3. A conductor for a source electrode 8 is formed of a metal contacting both the N⁺-type source region 3 and the P⁺-type contact layer 7. A conductor for a drain electrode 9 is formed of a metal contacting the N⁺-type drain region 4. Although an n-channel-type MOSFET is described in this specific example for simplicity, the same applies to a p-channel-type MOSFET if p and n are reversed.

FIG. 12 is a characteristic diagram showing the distribution of impurity concentrations along the line X-X′ inside the surface facing the gate electrode 6 across the gate oxide film 5 in FIG. 11, and the abscissa indicates the distance between X and X′, and the ordinate indicates the absolute value of difference between the impurity concentration of the N-layer and the P-layer (|impurity concentration of N-layer−impurity concentration of P-layer|). As the distribution of impurity concentrations shown in FIG. 12, the impurity concentration of the channel region underneath the gate electrode 6 is constant. The case wherein a voltage of the threshold voltage or higher is impressed to the gate electrode will be described. When a voltage is gradually impressed between the drain and the source, a drain current starts flowing; when the drain voltage reaches “the gate voltage−the threshold voltage”, the drain side of the channel region (right side in the drawing) becomes in a pinch-off state.

The pinch-off state is produced in the boundary between the linear region and the saturated region, and a gate-drain voltage is impressed to the regions in the pinch-off state to raise the electric field. If a carrier current flows in the high electric field region, avalanche breakdown occurs, and a hole-electron pair is produced. A hole current flows toward the source electrode side to become the base current of a parasitic NPN transistor composed of the N⁺-type source region 3, the P-type semiconductor layer 2, and the N⁺-type drain region 4. When the parasitic NPN transistor is activated, a large current flows and the current concentrates in a certain place to result in physical breakdown. Furthermore, electrons passing through a high electric field region produce high energy and are trapped in the oxide film, which may cause the threshold voltage to vary. In order to reduce such troubles, various methods have been proposed such as described in Japanese Patent Applications Laid-Open Nos. 2002-319631, 2003-086790, 3-156977 and 8-107202: however, the above-described problems have not been completely solved.

### SUMMARY OF THE INVENTION

A semiconductor device according to a basic configuration includes a second conductivity type layer selectively formed by changing impurity concentrations on a semiconductor substrate, a first conductivity type source region formed on the second conductivity type layer, a first conductivity type drain region formed on the second conductivity type layer apart from the first conductivity type source region, a gate electrode formed between the first conductivity type source region and the first conductivity type drain region across an insulation film, and a second conductivity type contact layer formed adjacent to the first conductivity type source region, wherein the second conductivity type layer in the source region side has a higher impurity concentration than the impurity concentration of the second conductivity type layer in the drain region side.

### BRIEF DESCRIPTION OF THE DRAWINGS

FIG. 1 is a sectional view showing a schematic configuration of a semiconductor device according to the first embodiment;

FIG. 2 is a characteristic diagram showing change in the absolute values of difference in impurity concentrations between Y and Y′ in FIG. 1;

FIG. 3 is a block diagram showing the configuration of an IC on the same substrate containing a semiconductor device of the present application;

FIG. 4 is a characteristic diagram showing relationship between drain currents and drain-source voltages of the control circuit and output elements shown in FIG. 3;

FIG. 5 is a characteristic diagram showing relationship between drain currents and gate voltages of the control circuit and output elements shown in FIG. 3;

FIG. 6 is a characteristic diagram showing relationship between the threshold voltages and applying time shown in FIG. 5;

FIG. 7 is a sectional view showing a schematic configuration of a semiconductor device according to the second embodiment;

FIG. 8 is a sectional view showing a schematic configuration of a semiconductor device according to the third embodiment;

FIG. 9 is a sectional view showing a configuration of a semiconductor device according to the fourth embodiment;

FIG. 10 is a sectional view showing a configuration of a semiconductor device according to the fifth embodiment;

FIG. 11 is a sectional view showing a schematic configuration of a conventional semiconductor device; and

FIG. 12 is a characteristic diagram showing a change in the absolute values of difference in impurity concentration between X and X′ in FIG. 11.

### DETAILED DESCRIPTION OF THE EMBODIMENTS

The embodiments of the semiconductor device will be described below referring to the attached drawings. In the drawings, the configuration element denoted by the same reference numerals used in other drawings shows the same or relevant configuration element in other configuration examples.

### First Embodiment

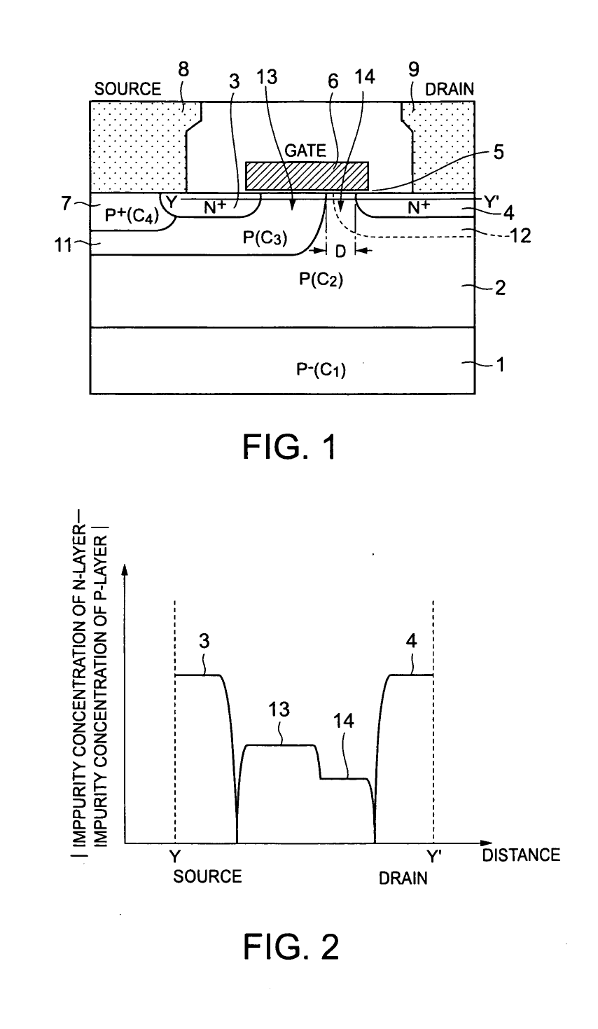

FIG. 1 is a sectional view showing a configuration of a semiconductor device according to a first embodiment. In FIG. 1, the semiconductor device according to the first embodiment includes a P-type well region 1 as a second conductivity type, a P-type base layer 2 selectively formed on the P-type well region 1, an N⁺-type source region 3 as a first conductivity type formed on the P-type base layer 2, and an N⁺-type drain region 4 formed on the P-type base layer 2 apart from the source region 3. Between the N⁺-type source region 3 and the N⁺-type drain region 4, a gate electrode 6 is formed across the gate oxide film 5, and a P⁺-type contact layer 7 is formed adjacent to the N⁺-type source region 3.

A conductor 8 for a source electrode is formed so as to include a conductor for electrically connecting the P⁺-type contact layer 7 to the N⁺-type source region 3 at an identical potential, and a conductor 9 for a drain electrode makes electrical contact with the N⁺-type drain region 4. In the example shown in FIG. 1, the P-type base layer 2 has a P-type region 11 of a somewhat higher impurity concentration wherein the region starting at the P⁺-type contact layer 7 to about ⅔ of the area from the bottom of the N⁺-type source region 3 to the channel region on the bottom of the gate electrode 6 becomes a high-concentration impurity region 13, and provides a depletion layer 12 wherein the region starting at the bottom of the N⁺-type drain region 4 to the remaining about ⅓ of the channel region on the bottom of the gate electrode 6 in the P-type base layer 2 overlaps a low-concentration impurity region 14. Although it was described that the P⁺-type contact layer 7 and the N⁺-type source region 3 have an identical potential, they can have different potentials. The distance D as shown in FIG. 1 between the P-type region 11 and the N⁺-type drain region 4 is at least 0.1 μm.

In the above configuration, the impurity concentration of the P-type base layer 2 as a second conductivity type under the gate electrode 6 is set to be higher than the impurity concentration of the P-type well region 1 as a second conductivity type. FIG. 2 shows impurity concentrations in the cross section along the line Y-Y′ in FIG. 1, from the N⁺-type source region 3 through the channel region to the N⁺-type drain region 4; more specifically, in this embodiment, as shown in FIG. 2, the P-type region 11 has the high-concentration impurity region 13, the P-type base layer 2 has the low-concentration impurity region 14, and the impurity concentration of the P-type base layer 2 is designed to be lower than the impurity concentration of the P-type region 11.

By thus designing, the depletion layer 12 can easily extend in the channel direction at a drain voltage higher than the pinch-off voltage, and the electric field can be relaxed. By relaxing the electric field, the hole current generated by avalanche breakdown can be reduced, and a parasitic NPN transistor is prevented from turning on. As FIG. 1 shows, when the impurity concentrations of the P-type well region 1, the P-type base layer 2, the P-type region 11 and the P⁺-type contact layer 7 are C₁, C₂, C₃ and C₄, respectively, the relationship between concentrations is C₁<C₂<C₃<C₄. As specific concentration values, for example, when the thickness of the gate oxide film 5 is 14 nm, the concentration C₃ is about “2×10¹⁷ cm⁻³”, and the concentration C₂ is “1×10¹⁷ cm⁻³” or below.

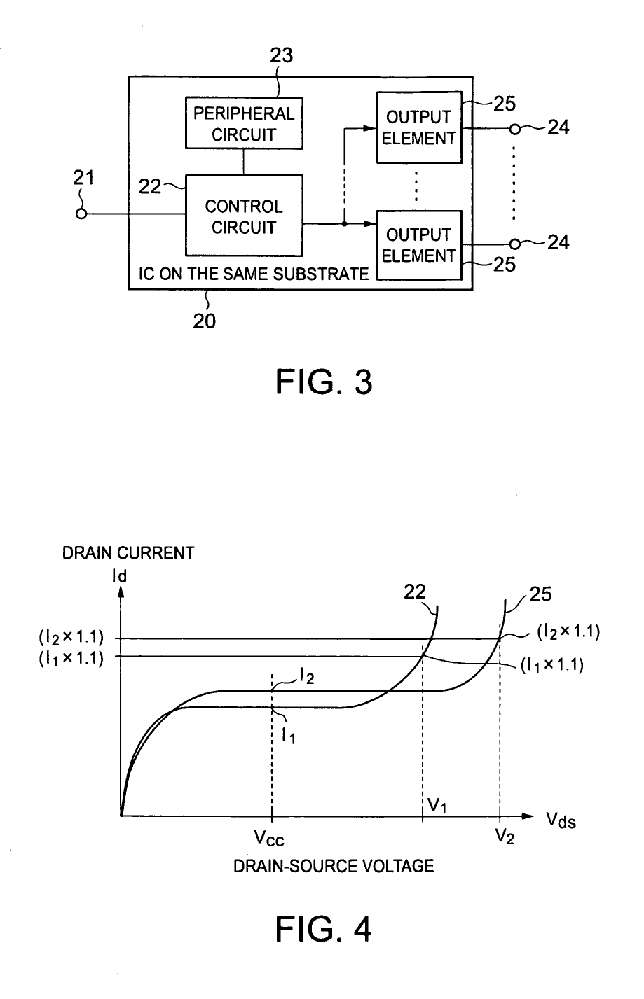

The semiconductor device according to the first embodiment shown in FIG. 1 is used as an output element in an IC (integrated circuit) chip on the same substrate as shown in FIG. 3. FIG. 3 is a block diagram showing a schematic configuration of an IC chip wherein the semiconductor device of the first embodiment is integrated with a semiconductor device of a conventional configuration on the same substrate. In FIG. 3, the IC chip 20 is provided with a control circuit 22 composed of a CMOS or the like that receives the input 21, performs logic operations, and outputs the results; a peripheral circuit 23, such as an analog circuit; and output elements 25 that output the results of operation from the control circuit 22 out of the chip through output terminals 24.

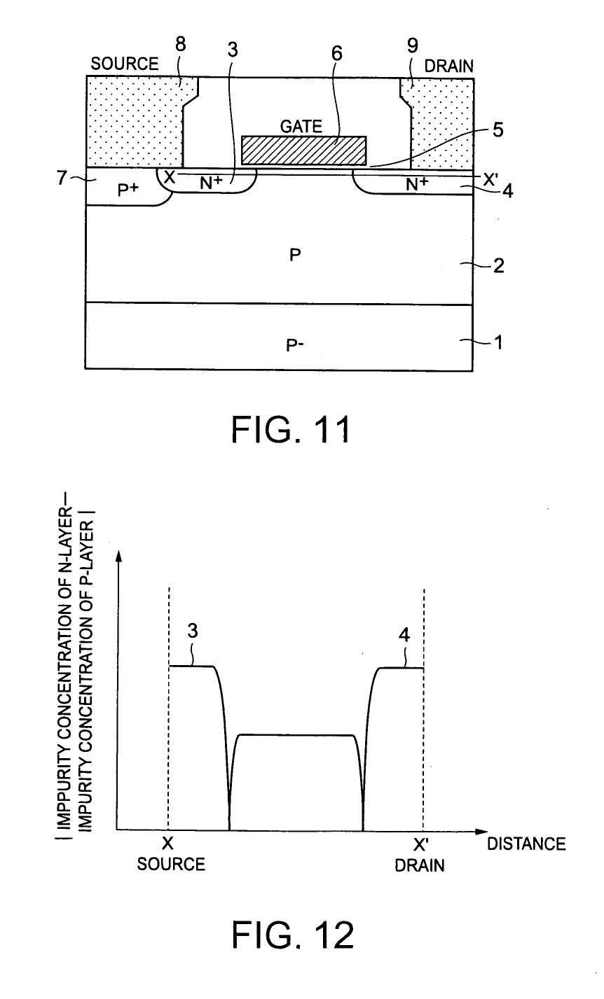

The control circuit 22 has a conventional structure, for example, as described using FIG. 11, which includes the case where the N⁺-type source region 3 and P⁺-type contact region 7 have different potentials, respectively, and the output elements 25 have the configuration of the first embodiment, for example, shown in FIG. 1. Therefore, in the distribution of impurity concentration over the channel region across the insulation film 5 under the gate electrode 6, although each of the output elements 25 has both high-concentration impurity region 13 and low-concentration impurity region 14 as shown in FIG. 2, the impurity concentration in the control circuit 22 has impurity concentrations shown in FIG. 12.

FIG. 4 shows the relationship between the drain current Id and the drain-source voltage V_{ds} in both elements corresponding to the case having the same gate length on the basis of such difference in configuration. The abscissa indicates the drain-source voltage V_{ds}, and the ordinate indicates the drain current I_{d}. In FIG. 4, when the V_{ds} is the rated voltage V_{cc} being the drain voltage which operates in the saturated region at or under the discontinuity point, the drain current I_{d} is I₁ in the wave form of the MOSFET applied to the control circuit 22, the drain current I_{d} is I₂ in the wave form of the output elements 25; and when the voltage V_{ds} at the current value of 1.1 times each of I₁ and I₂, the drain-source voltage V_{ds} becomes the voltage values as shown in FIG. 4, and has the relationship to be V₁<V₂. Thus, since the output elements 25 to which the configuration of the first embodiment is applied can reduce the avalanche current even at a high drain voltage compared with the MOSFET applied to the control circuit 22, the voltage at the discontinuity point of the drain can be elevated.

Accordingly, FIG. 4 shows the following condition where a first transistor of the control circuit 22 has a first curve 22 of a relationship of a drain current I_{d} and a drain-source voltage V_{ds}, and a second transistor of the output element 25 has a second curve 25 of the relationship of the drain current I_{d} and the drain-source voltage V_{ds}, in which the first and second curve 22 and 25 have a first and second discontinuity points, respectively, and the drain-source voltage V₂ at the second discontinuity point is higher than the drain-source voltage V₁ at the first discontinuity point, in condition that a gate-source voltage and a gate length of the first transistor are the same as those of the second transistor.

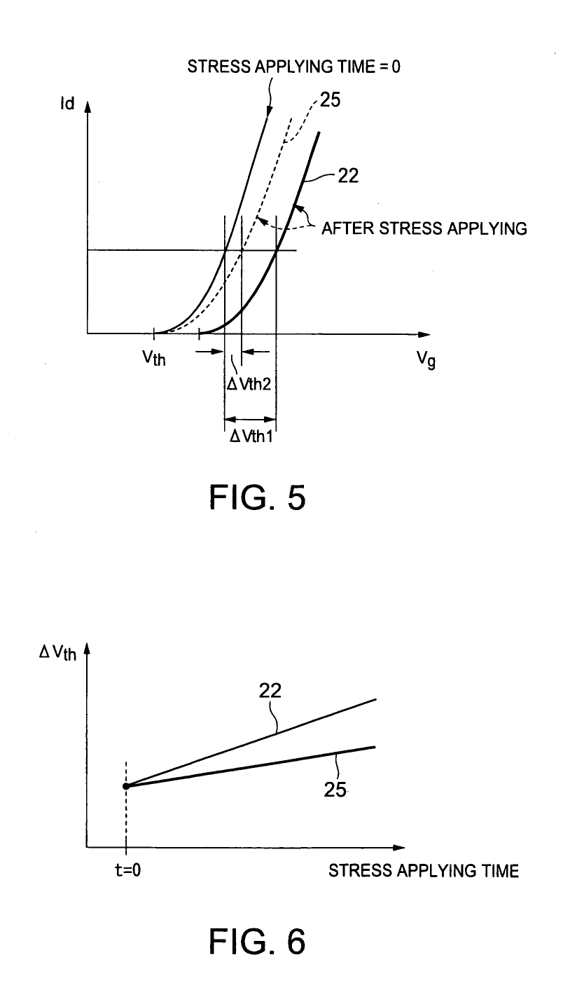

In addition, in FIG. 1, since the depletion layer 12 is easily extended in the channel direction, and the electric field in this region is relaxed, the improvement of reliability to hot carrier can be expected. FIG. 5 shows a characteristic diagram representing the variation of the threshold voltage in continuous operation under a bias condition wherein the electric field in the drain side becomes strongest. In this case, the condition is that the gate length of the element of the control circuit has the same length of those of the output elements 25. In FIG. 5, the abscissa indicates the gate voltage V_{g}, and the ordinate indicates the drain current I_{d}. Before applying stress, the threshold voltage of the MOSFET applied to the output elements 25 is the same as the threshold voltage of the MOSFET applied to the control circuit 22. When the I_{d}−V_{g} characteristics after sufficiently applying stress are checked, the variation width ΔVₜₕ₂ of the threshold voltages of the MOSFET in the output elements 25 is smaller than the variation width ΔVₜₕ₁ of the threshold voltages of the MOSFET used in the control circuit 22. This is because the probability of the occurrence of hot carriers is lowered due to the relaxation of the electric field.

FIG. 6 is a characteristic diagram showing the relationship between the variation width ΔVₜₕ of the threshold voltages and applying time. As is obvious from FIGS, 5 and 6, the semiconductor device 25 by the configuration of the first embodiment can suppress the variation width ΔVₜₕ of the threshold voltages compared with the semiconductor device 22 of the conventional configuration, and the relationship between the variation width ΔVₜₕ of the threshold voltages and the stress applying time becomes a more gentle gradient in the MOSFET used in the output elements 25 than in the MOSFET applied to the control circuit 22. It is known that the reliability to hot carriers is also improved by such characteristics.

The basic concept of the first embodiment is applied to second through fifth embodiments. For example, the impurity concentration in FIG. 2, transistors in FIG. 3 and current-voltage characteristics in FIG. 4 are applied to the second through fifth embodiments.

### Second Embodiment

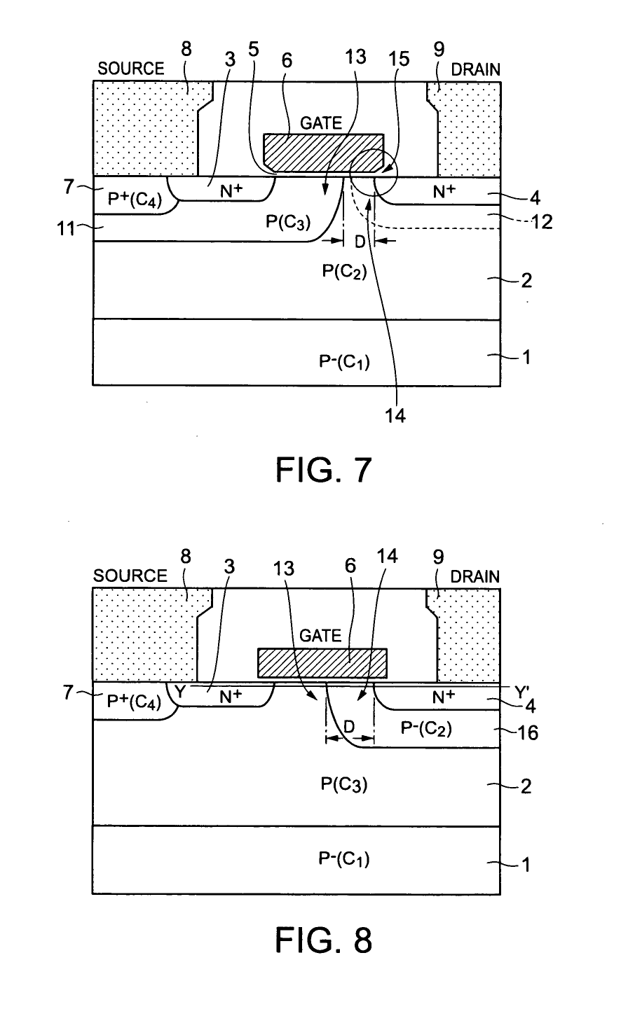

FIG. 7 is a sectional view showing the configuration of a semiconductor device according to the second embodiment. Since the place in a semiconductor device such as an output element where avalanche breakdown is most likely to occur is the edge of a drain region, in the semiconductor device of the second embodiment, in order to relax the electric field in the area where the avalanche breakdown easily occurs, only the portions of the gate oxide film 15 at the edges of the gate 6, in the gate oxide film 5 corresponding to the edges of the drain region 4, is thickened. Other configuration is substantially same as the configuration of the semiconductor device in the first embodiment.

In the second embodiment, the aspect wherein the concentration of the P-type impurity in the region on the side of the source region 3 is higher than in the region 14 on the side of the drain region 4 in the channel region opposed to the gate electrode 6 via the gate oxide film 5 is the same as in the first embodiment shown in FIG. 1, but the aspect wherein a thick gate oxide film 15 is formed in addition to the configuration of the first embodiment is different. Therefore, the relationship of difference in impurity concentrations in the P-type region is similar to the semiconductor device in the first embodiment, the relationship of impurity concentrations between the P-type well layer 1 (C₁), the P-type base layer 2 (C₂), the P-type region 11 (C₃) and the P-type contact layer 7 (C₄) is C₁<C₂<C₃<C₄ as in the first embodiment. Also in the second embodiment, the distance D as shown in FIG. 7 between the P-type region 11 and the drain region 4 is at least 0.1 μm.

### Third Embodiment

FIG. 8 is a sectional view showing the configuration of a semiconductor device according to the third embodiment. The semiconductor devices in the first and second embodiment are constituted so that the region 13 of the second conductivity type layer 11 in the side of the source region 3 has a higher impurity concentration than the region 14 of the second conductivity type layer 2 in the side of the drain region 4, by forming a P-type region 11 having a concentration C₃ so that the side of the source region 3 of the channel region facing the bottom surface of the gate electrode 6 through the gate oxide film 5 on the upper layer of the P-type base layer 2 has a higher impurity concentration; however, in the semiconductor device in the third embodiment, a second conductivity type electric field relaxing layer 16 having a low impurity concentration (C₂) is formed in the side of the drain region 4 in the P-type base layer 2.

Specifically, in the semiconductor device according to the third embodiment, as FIG. 8 shows, a P-type layer as a second conductivity type layer formed between the second conductivity type well region 1 and the first conductivity type source and drain regions 3 and 4 is composed of a P-type base layer 2 having a high impurity concentration selectively formed on the P-type well region 1 to have a different impurity concentration, and a P-type electric field relaxing layer 16 having a lower impurity concentration than the base layer 2. Furthermore, the semiconductor device in the third embodiment includes an N-type drain region 4 as the first conductivity type formed on the P-type electric field relaxing layer 16 as the second conductivity type, an N-type source region 3 formed on the second conductivity type base layer 2 apart from the N-type drain region 4, a gate electrode 6 formed across a gate oxide film 5 as an insulation film between the N-type drain region 4 and the N-type source region 3, a P-type contact layer 7 formed adjacent to the N-type source region 3, a source conductor 8 that electrically connects the N-type source region 3 to the P-type contact layer 7 at the same potential, and a drain conductor 9 that electrically connects the source conductor 8 to the N-type drain region 4.

Such a configuration of the third embodiment is formed so that the impurity concentration of the P-type base layer 2 is higher than the impurity concentration of the P-type well region 1, and the region 13 in the P-type base layer 2 in the side of the N-type source region 3 has a higher impurity concentration than the region 14 in the P-type electric field relaxing layer 16 in the side of the N-type drain region 4. Specifically, as FIG. 8 shows, when the impurity concentrations of the P-type well region 1, the P-type electric field relaxing layer 16, the P-type base layer 2, and the P-type contact layer 7 are C₁, C₂, C₃ and C₄, respectively, the relationship of C₁<C₂<C₃<C₄ is established as in semiconductor devices in the first and second embodiments. The P-type electric field relaxing layer 16 can be formed by the ion implantation of an N-type impurity into the P-type well region 1.

Since the impurity profile as shown in FIG. 8 is realized by thus changing the impurity concentration of the P-type electric field relaxing layer 16 in the side of the drain region 4, the electric field of the pinch-off region can be relaxed as in the semiconductor devices according to the first and second embodiments, and thereby, the parasitic NPN transistor is prevented from turning on, and the deterioration of hot carriers can be suppressed.

Also in the third embodiment shown in FIG. 8, although the P⁺-type contact layer 7 is described to have the same potential as the N⁺-type source layer 3, the potential can be different. The width of the surface of the P-type electric field relaxing layer 16 facing the gate electrode 6 across the gate oxide film 5, that is the distance D as shown in FIG. 8 between the P-type base layer 2 and the drain region 4 is at least 0.1 μm.

### Fourth Embodiment

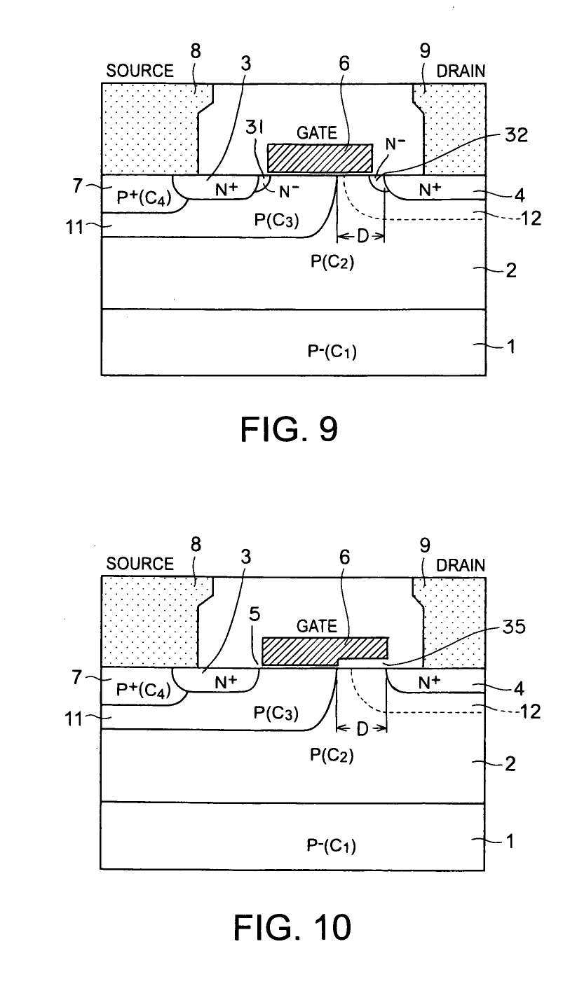

FIG. 9 is a sectional view showing the configuration of a semiconductor device according to the fourth embodiment. In FIG. 9, a diffusion layer 31 is provided between the N⁺-type source layer 3 and the gate electrode 6. The diffusion layer 31 has an impurity concentration lower than that of the N⁺-type source layer 3. In the same manner, a diffusion layer 32 is provided between the N⁺-type drain layer 4 and the gate electrode 6. The diffusion layer 32 has an impurity concentration lower than that of the N⁺-type source layer 3. The diffusion layers 31 and 32 are formed in the same an ion implanting process.

The impurity concentration of the diffusion layer 31 is slightly lower than that of the diffusion layer 32, but the impurity concentrations thereof are substantially the same. The provision of the diffusion layers 31 and 32 causes the depletion layer 12 to extend to the side of the diffusion layer 32, thereby relaxing the electric field of the edge of the gate electrode 6 at the side of the drain region 4. Accordingly, it is possible for the fourth embodiment to improve the reliability of the device.

### Fifth Embodiment

FIG. 10 is a sectional view showing the configuration of a semiconductor device according to the fifth embodiment. In FIG. 10, a thick gate oxide film 35 is provided between the drain side of the gate electrode 6 and the low-impurity concentration diffusion layer 2. The gate oxide film 35 has a thickness more than that of the gate oxide film 5 between the source side of the gate electrode 6 and the P-type region 11.

In FIG. 10, even though the thick gate oxide layer 35 has a step portion, the thick gate oxide layer 35 may have a slant portion. The thick gate oxide layer 35 causes the depletion layer 12 to extend toward the portion under the gate electrode 6, thereby relaxing the electric field of the edge of the gate electrode 6 at the side of the drain region 4. Accordingly, it is possible for the fifth embodiment to improve the reliability of the device.

When the entire thickness of the gate oxide layers 5 and 35 is caused to be thickened, a threshold voltage and a channel resistance increase generally. In contrast, the gate oxide layer 5 on the side of the source region 3 is formed to be thin in the fifth embodiment, and it is possible to suppress the increase of a threshold voltage and an on-resistance.

In the first to fifth embodiments, although the configurations wherein the first conductivity is N-type and the second conductivity is P-type are described, the semiconductor devices described herein are not limited thereto, but the same effects can be obtained when the first conductivity is P-type and the second conductivity is N-type. In addition, various modifications and changes can be executed within the range not deviating from the gist of the present application. For example, in order to relax the electric field at the edge of the drain region where avalanche breakdown occurs most easily, the thickness of the oxide film 5 at the edge of the gate electrode 6 corresponding to the edge of the drain region 4 can be thickened as the gate oxide film 15 shown in FIG. 7 by combining the configurations of the thick gate oxide film 15 in the second embodiment shown in FIG. 7 to the third embodiment shown in FIG. 8.

What is claimed is:

1. A semiconductor device comprising:
a second conductivity type layer selectively formed by changing impurity concentrations on a semiconductor substrate, a first conductivity type source region formed on the second conductivity type layer, a first conductivity type drain region formed on the second conductivity type layer apart from the first conductivity type source region, a gate electrode formed between the first conductivity type source region and the first conductivity type drain region across an insulation film, and a second conductivity type contact layer formed adjacent to the first conductivity type source region, wherein
the second conductivity type layer in the source region side has a higher impurity concentration than the impurity concentration of the second conductivity type layer in the drain region side.

2. The semiconductor device according to claim 1, wherein
the second conductivity type layer includes a high-concentration impurity region which is provided under the second conductivity type contact layer, the first conductivity type source region, and a source side portion of the gate electrode.

3. The semiconductor device according to claim 2, wherein
the second conductivity type layer includes a low-concentration impurity region overlapping the portion of a drain side portion of the gate electrode.

4. The semiconductor device according to claim 3, wherein
when the impurity concentration in the high-concentration impurity region in the second conductivity type layer is C₃, the impurity concentration in the low-concentration impurity region overlapping the drain side portion of the gate electrode is C₂, and the impurity concentration in a second conductivity type well layer underneath the second conductivity type layer is C₁, the relation ship at least of C₁<C₂<C₃ is established.

5. The semiconductor device according to claim 3, wherein
the distance between the second conductivity type layer having the high-concentration impurity and the first conductivity type drain region is at least 0.1 μm.

6. The semiconductor device according to claim 3, wherein
when the thickness of the insulation film that insulates the gate electrode from the source region/the drain region is 14 nm, the impurity concentration of the second conductivity type layer in the source region side is 2×10¹⁷ cm⁻³, and the impurity concentration of the second conductivity type layer in the drain region side is 1×10¹⁷ cm⁻³.

7. The semiconductor device according to claim 3, wherein
the semiconductor device having a high-concentration impurity region and a low-concentration impurity region in the second conductivity type layer is used as an output element of an IC chip on the same substrate, and the IC chip includes a control circuit containing at least a CMOS to receive inputs, perform logic operation, and output the results, a peripheral circuit containing at least an analog circuit, and the output element to externally output the results of operations performed by the control circuit through output terminals.

8. The semiconductor device according to claim 7, wherein
a first transistor of the control circuit has a first curve of a relationship of a drain current and a drain-source voltage, and a second transistor of the output element has a second curve of the relationship of the drain current and the drain-source voltage, in which the first and second curve have a first and second discontinuity points, respectively, and the drain-source voltage at the second discontinuity point is higher than the drain-source voltage at the first discontinuity point, in condition that a gate-source voltage and a gate length of the first transistor are the same as those of the second transistor.

9. The semiconductor device according to claim 1, wherein
the insulation film between the gate electrode and the first conductivity type drain region has a thickness larger than the thickness of the insulation film present between the gate electrode and the second conductivity type layer.

10. The semiconductor device according to claim 1, wherein
the second conductivity type layer is composed of a second conductivity type electric field relaxing region, and a second conductivity type base layer formed adjacent thereto having an impurity concentration different from the impurity concentrations of the second conductivity type electric field relaxing region; and the second conductivity type layer has a higher impurity concentration than the impurity concentration of the second conductivity type electric field relaxing region.

11. The semiconductor device according to claim 10, wherein
the insulation film between the gate electrode and the first conductivity type drain region has a thickness larger than the thickness of the insulation film present between the gate electrode and the second conductivity type base layer.

12. The semiconductor device according to claim 10, wherein
the second conductivity type electric field relaxing region is selectively formed on the second conductivity type base layer.

13. The semiconductor device according to claim 12, wherein
the distance between the second conductivity type base layer and the first conductivity type drain region is at least 0.1 μm.

14. A semiconductor device comprising:
a second conductivity type layer selectively formed by changing impurity concentrations on a semiconductor substrate, a first conductivity type source region formed on the second conductivity type layer, a first conductivity type drain region formed on the second conductivity type layer apart from the first conductivity type source region, a gate electrode formed between the first conductivity type source region and the first conductivity type drain region across an insulation film, and a second conductivity type contact layer formed adjacent to the first conductivity type source region, wherein
the second conductivity type layer in the source region side has a higher impurity concentration than the impurity concentration of the second conductivity type layer in the drain region side, and wherein
a first diffusion layer of the first conductivity type is provided between the first conductivity type source layer and the gate electrode, the first diffusion layer which has an impurity concentration lower than that of the first conductivity type source layer, a second diffusion layer of the first conductivity type is provided between the first conductivity type drain layer and the gate electrode, the second diffusion layer which has an impurity concentration lower than that of the first conductivity type source layer, and the first and second diffusion layers are formed in a same ion implanting process.

15. The semiconductor device according to claim 14, wherein
the second conductivity type layer includes a high-concentration impurity region which is provided under the second conductivity type contact layer, the bottom of the first conductivity type source region, and a source side portion of the gate electrode,
the second conductivity type layer includes a low-concentration impurity region overlapping the portion of a drain side portion of the gate electrode, and
when the impurity concentration in the high-concentration impurity region in the second conductivity type layer is C₃, the impurity concentration in the low-concentration impurity region overlapping the drain side portion of the gate electrode is C₂, and the impurity concentration in a second conductivity type well layer underneath the second conductivity type layer is C₁, the relation ship at least of C₁<C₂<C₃ is established.

16. The semiconductor device according to claim 14, wherein
the semiconductor device having a high-concentration impurity region and a low-concentration impurity region in the second conductivity type layer is used as an output element of an IC chip on the same substrate, and the IC chip includes a control circuit containing at least a CMOS to receive inputs, perform logic operation, and output the results, a peripheral circuit containing at least an analog circuit, and the output element to externally output the results of operations performed by the control circuit through output terminals.

17. The semiconductor device according to claim 16, wherein
a first transistor of the control circuit has a first curve of a relationship of a drain current and a drain-source voltage, and a second transistor of the output element has a second curve of the relationship of the drain current and the drain-source voltage, in which the first and second curve have a first and second discontinuity points, respectively, and the drain-source voltage at the second discontinuity point is higher than the drain-source voltage at the first discontinuity point, in condition that a gate-source voltage and a gate length of the first transistor are the same as those of the second transistor.

18. A semiconductor device comprising:
a second conductivity type layer selectively formed by changing impurity concentrations on a semiconductor substrate, a first conductivity type source region formed on the second conductivity type layer, a first conductivity type drain region formed on the second conductivity type layer apart from the first conductivity type source region, a gate electrode formed between the first conductivity type source region and the first conductivity type drain region across an insulation film, and a second conductivity type contact layer formed adjacent to the first conductivity type source region, wherein
the second conductivity type layer in the source region side has a higher impurity concentration than the impurity concentration of the second conductivity type layer in the drain region side, and wherein
a thick gate oxide film is provided between the drain side of the gate electrode and the low-impurity concentration diffusion layer, the thick gate oxide film which has a thickness more than that of the gate oxide film between the source side of the gate electrode and the second conductivity type region.

19. The semiconductor device according to claim 18, wherein
the semiconductor device having a high-concentration impurity region and a low-concentration impurity region in the second conductivity type layer is used as an output element of an IC chip on the same substrate, and the IC chip includes a control circuit containing at least a CMOS to receive inputs, perform logic operation, and output the results, a peripheral circuit containing at least an analog circuit, and the output element to externally output the results of operations performed by the control circuit through output terminals.

20. The semiconductor device according to claim 19, wherein
a first transistor of the control circuit has a first curve of a relationship of a drain current and a drain-source voltage, and a second transistor of the output element has a second curve of the relationship of the drain current and the drain-source voltage, in which the first and second curve have a first and second discontinuity points, respectively, and the drain-source voltage at the second discontinuity point is higher than the drain-source voltage at the first discontinuity point, in condition that a gate-source voltage and a gate length of the first transistor are the same as those of the second transistor.
